(19) United States
(12) Patent Application Publication
(10) Pub. No.: US 2026/0156931 A1
(43) Pub. Date: Jun. 4, 2026

(54) SEMICONDUCTOR DEVICE AND METHOD FOR FABRICATING THE SAME

(71) Applicant: Samsung Electronics Co., Ltd., Suwon-si (KR)

(72) Inventors: In Hyun SONG, Suwon-si (KR); Young Hwan JANG, Suwon-si (KR); Jin Kyu KIM, Suwon-si (KR); Kyoung Woo LEE, Suwon-si (KR); Myung Jin CHUNG, Suwon-si (KR); Eun Guk CHUNG, Suwon-si (KR); Keun Hwi CHO, Suwon-si (KR); Wook Hyun JO, Suwon-si (KR); Su Haeng HEO, Suwon-si (KR)

(21) Appl. No.: 19/266,660

(22) Filed: Jul. 11, 2025

(30) Foreign Application Priority Data
Dec. 2, 2024 (KR) 10-2024-0176604

(51) Int. Cl. H10D 84/85; H10D 84/01

(52) U.S. Cl. CPC H10D 84/851; H10D 84/0186

(57) ABSTRACT

A semiconductor device including a backside power delivery network (BSPDN) and a method for fabricating the same are provided. The semiconductor device includes a semiconductor substrate including a first side and a second side that is on an opposite side of the semiconductor substrate from the first side, an active pattern on the first side, a gate structure that intersects the active pattern, a source/drain region connected to the active pattern, on a side face of the gate structure, a front wiring structure connected to at least one of the gate structure or the source/drain region, on the first side, a back wiring structure on the second side, and a contact pattern in the semiconductor substrate, wherein the contact pattern is connected to the back wiring structure, wherein a height of the contact pattern in a vertical direction intersecting the first side is smaller than a thickness of the semiconductor substrate in the vertical direction.

### CROSS-REFERENCE TO RELATED APPLICATION

This application claims priority from Korean Patent Application No. 10-2024-0176604, filed on Dec. 2, 2024 in the Korean Intellectual Property Office and all the benefits accruing therefrom under 35 U.S.C. 119, the contents of which in its entirety are herein incorporated by reference.

### BACKGROUND

### 1. Technical Field

The present inventive concepts relate to a semiconductor device and a method for fabricating the same. More specifically, the present inventive concepts relate to a semiconductor device including a backside power delivery network (BSPDN) and a method for fabricating the same.

### 2. Description of the Related Art

Due to characteristics such as a miniaturization, a multi-functionality, and/or a low fabricating cost, semiconductor devices are in the spotlight as important elements in the electronics industry. The semiconductor devices may be classified into a semiconductor memory device that stores logical data, a semiconductor logic device that performs a computation process on the logical data, and a hybrid semiconductor device that includes memory elements and logic elements.

As the electronics industry develops to a high level, the demands for the characteristics of the semiconductor devices are increasing. For example, the demands for a high reliability, a high speed, and/or a multi-functionality of the semiconductor devices are increasing. To satisfy these characteristics, the structures inside the semiconductor device are becoming complex and highly integrated.

On the other hand, as the semiconductor devices become highly integrated, widths of wiring patterns and via patterns that realize the semiconductor device are decreasing. For this reason, a voltage drop (e.g., IR drop) of a power delivery network (PDN) that supplies a power supply voltage to the integrated circuit has become an important problem.

### SUMMARY

Aspects of the present inventive concepts provide a semiconductor device for which it is easier to perform a failure analysis.

Aspects of the present inventive concepts also provide a method for fabricating a semiconductor device in which PVC sensitivity is improved.

Aspects of the present inventive concepts are not restricted to those set forth herein. The above and other aspects of the present inventive concepts will become more apparent to one of ordinary skill in the art to which the present inventive concepts pertain by referencing the detailed description of the present inventive concepts given below.

According to an aspect of the present inventive concept, there is provided a semiconductor device comprising a semiconductor substrate including a first side and a second side that is on an opposite side of the semiconductor substrate from the first side, an active pattern on the first side, a gate structure that intersects the active pattern, a source/drain region connected to the active pattern, on a side face of the gate structure, a front wiring structure connected to at least one of the gate structure or the source/drain region, on the first side, a back wiring structure on the second side, and a contact pattern in the semiconductor substrate, wherein the contact pattern is connected to the back wiring structure,, wherein a height of the contact pattern in a vertical direction intersecting the first side is smaller than a thickness of the semiconductor substrate in the vertical direction.

According to an aspect of the present inventive concept, there is provided a semiconductor device comprising a semiconductor substrate including a first side and a second side that is on an opposite side of the semiconductor substrate from the first side, an active pattern on the first side, a gate structure that intersects the active pattern, a source/drain region connected to the active pattern, on a side face of the gate structure, a front wiring structure connected to the source/drain region, on the first side, a contact pattern in the semiconductor substrate, wherein the contact pattern is spaced apart from the gate structure and from the source/drain region, a first back wiring pattern connected to the contact pattern, on the second side, a second back wiring pattern separated from the first back wiring pattern, and a through via that extends in a vertical direction crossing the first side, and connects the front wiring structure and the second back wiring pattern.

According to an aspect of the present inventive concept, there is provided a semiconductor device including a first region and a second region, the semiconductor device comprising a semiconductor substrate including a first side and a second side that is on an opposite side of the semiconductor substrate from the first side, a first active pattern on the first side of the first region, a first gate structure that intersects the first active pattern, a first source/drain region connected to the first active pattern, on a side face of the first gate structure, a second active pattern on the first side of the second region, a second gate structure that intersects the second active pattern, a second source/drain region connected to the second active pattern, on a side face of the second gate structure, an interlayer insulating film that covers the first gate structure, the first source/drain region, the second gate structure, and the second source/drain region, on the first side, a front wiring structure on the interlayer insulating film, a first back wiring pattern on the second side of the first region, a second back wiring pattern on the second side of the second region, which second back wiring pattern is separated from the first back wiring pattern, a back source/drain contact that penetrates the semiconductor substrate of the first region, and connects the first source/drain region and the first back wiring pattern, and a contact pattern in the semiconductor substrate of the second region, wherein the contact pattern is connected to the second back wiring pattern, wherein a first thickness of the semiconductor substrate of the first region is smaller than a second thickness of the semiconductor substrate of the second region, in a vertical direction intersecting the first side, and a first height of the back source/drain contact in the vertical direction is larger than a second height of the contact pattern in the vertical direction.

### BRIEF DESCRIPTION OF THE DRAWINGS

The above and other aspects and features of the present inventive concepts will become more apparent by describing in detail exemplary embodiments thereof with reference to the attached drawings, in which:

FIG. 1 is a schematic cross-sectional view for explaining the semiconductor device according to some embodiments.

FIG. 2 is a schematic cross-sectional view for explaining a semiconductor device according to some embodiments.

FIG. 3 is a schematic cross-sectional view for explaining a semiconductor device according to some embodiments.

FIG. 4 is a schematic cross-sectional view for explaining a semiconductor device according to some embodiments.

FIG. 5 is a schematic cross-sectional view for explaining a semiconductor device according to some embodiments.

FIG. 6 is a schematic cross-sectional view for explaining a semiconductor device according to some embodiments.

FIG. 7 is a schematic cross-sectional view for explaining a semiconductor device according to some embodiments.

FIG. 8 is a schematic cross-sectional view for explaining a semiconductor device according to some embodiments.

FIGS. 9 to 18 are intermediate step diagrams for explaining a method for fabricating a semiconductor device according to some embodiments.

FIGS. 19 to 21 are intermediate step diagrams for explaining a method for fabricating a semiconductor device according to some embodiments.

FIGS. 22 to 24 are intermediate step diagrams for explaining a method for fabricating a semiconductor device according to some embodiments.

### DETAILED DESCRIPTION OF THE EMBODIMENTS

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present inventive concept. A first element, component, region, layer or section discussed herein in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

As used herein, the term “semiconductor device” may be for example a semiconductor chip (i.e., a semiconductor device singulated from (e.g., cut from) a wafer).

Items described in the singular herein may be provided in plural, as can be seen, for example, in the drawings. Thus, the description of a single item that is provided in plural should be understood to be applicable to the remaining plurality of items unless context indicates otherwise.

It will be understood that the terms “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

The term “same” as used herein when referring to orientation, layout, location, shapes, sizes, compositions, amounts, or other measures does not necessarily mean an exactly identical orientation, layout, location, shape, size, composition, amount, or other measure, but is intended to encompass nearly identical orientation, layout, location, shapes, sizes, compositions, amounts, or other measures within typical variations that may occur resulting from conventional manufacturing processes.

Spatially relative terms, such as “below,” “lower,” “upper,” “front,” “frontside”, “back,” “backside” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

It will be understood that when an element is referred to as being “connected” or “on” another element, it can be directly connected to or on the other element or intervening elements may be present. In contrast, when an element is referred to as being “directly connected” to another element, or as “contacting” or “in contact with” another element (or using any form of the word “contact”), there are no intervening elements present at the point of contact.

As used herein the terms “cover” and “covering” are intended to mean that an element is over or aside another element. An element “covering” another element need not cover an entire top surface of an element below to be considered “covering”. The terms are intended to encompass one element “covering” all, or any part of, an element below it.

As used herein, items described as being “electrically connected” are configured such that an electrical signal can be passed from one item to the other. Therefore, a passive electrically conductive component (e.g., a wire, pad, internal electrical line, etc.) physically connected to a passive electrically insulative component (e.g., a prepreg layer of a printed circuit board, an electrically insulative adhesive connecting two device, an electrically insulative underfill or mold layer, etc.) is not electrically connected to that component. In this specification, although MBCFET™ including multi-bridge channels are shown as an example of electronic elements included in the semiconductor device, this is merely an example. As another example, the semiconductor device may include a tunneling transistor (tunneling FET), a VFET (Vertical FET), a CFET (Complementary FET) or a three-dimensional (3D) transistor. Alternatively, the semiconductor device may include a bipolar junction transistor, a laterally-diffused metal-oxide semiconductor (LDMOS), and the like.

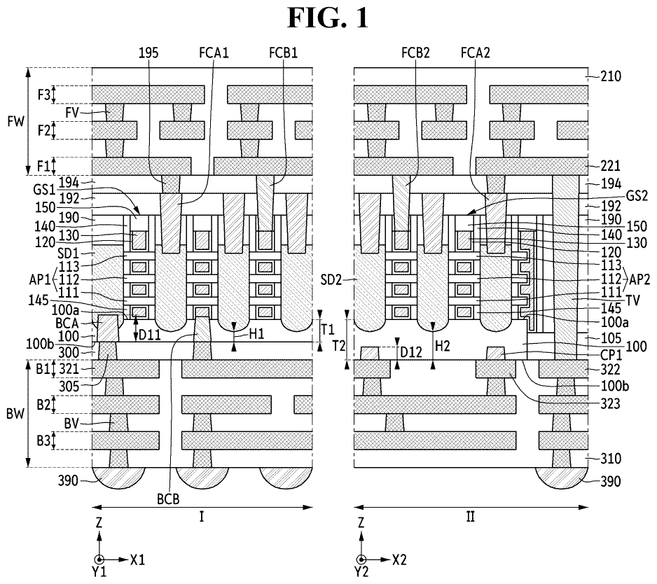

Hereinafter, a semiconductor device according to exemplary embodiments will be described referring to FIGS. 1 to 8.

FIG. 1 is a schematic cross-sectional view for explaining the semiconductor device according to some embodiments.

Referring to FIG. 1, the semiconductor device according to some embodiments includes a first region I and a second region II. The first region I and the second region II may be regions adjacent to each other, or may be regions separated from each other.

The first region I may be a region to which a backside power delivery network (BSPDN) is provided. For example, the first region I may be a cell region that uses the backside power delivery network in a semiconductor chip including the backside power delivery network. The cell region may be a logic cell region or a memory cell region such as a static random access memory (SRAM) cell.

The second region II may be a region to which a frontside power delivery network (FSPDN) is provided. For example, the second region II may be a core region, an analog region, and/or an input/output region that uses the frontside power delivery network in a semiconductor chip that includes the backside power delivery network.

Also, referring to FIG. 1, the semiconductor device according to some embodiments includes a semiconductor substrate 100, a first active pattern AP1, a second active pattern AP2, a first gate structure GS1, a second gate structure GS2, a first source/drain region SD1, a second source/drain region SD2, a first interlayer insulating film 190, a second interlayer insulating film 192, a third interlayer insulating film 194, a first source/drain contact FCA1, a first gate contact FCB1, a second source/drain contact FCA2, a second gate contact FCB2, a through via TV, a front wiring structure FW, a back source/drain contact BCA, a back gate contact BCB, a back insulating film 300, a first contact pattern CP1, a back wiring structure BW, and a connection terminal 390.

The semiconductor substrate 100 may be bulk silicon or silicon-on-insulator (SOI). In contrast, the semiconductor substrate 100 may be a silicon substrate, or may include other materials, for example, silicon germanium, silicon germanium on insulator (SGOI), indium antimonide, lead telluride, indium arsenide, indium phosphide, gallium arsenide or gallium antimonide. In examples, the semiconductor substrate 100 may be a substrate in which an epitaxial layer is formed on a base substrate.

The semiconductor substrate 100 may include a first side 100a and a second side 100b that are on opposite sides of the semiconductor substrate from each other. In the following description, the first side 100a may be referred to as a frontside of the semiconductor substrate 100, and the second side 100b may be referred to as a backside of the semiconductor substrate 100.

In some embodiments, in a vertical direction Z intersecting the first side 100a, a first thickness T1 of the semiconductor substrate 100 of the first region I may be smaller than a second thickness T2 of the semiconductor substrate of the second region II. In some embodiments, the second thickness T2 may be about 100 nm or less, or about 90 nm or less, and the first thickness T1 may be smaller than the second thickness T2. In some embodiments, the second thickness T2 may be less than about 70 nm, or less than about 60 nm, and the first thickness T1 may be smaller than the second thickness T2. For example, the second thickness T2 may be about 50 nm to about 70 nm, or about 55 nm to about 65 nm, and the first thickness T1 may be about 1 nm to about 40 nm, or about 5 nm to about 35 nm.

The first active pattern AP1 may be formed on the first side 100a of the first region I. The first active pattern AP1 may extend long in a first direction X1 parallel to the first side 100a.

The second active pattern AP2 may be formed on the first side 100a of the second region II. The second active pattern AP2 may extend long in a second direction X2 parallel to the first side 100a. The second direction X2 may be the same direction as the first direction X1 or may be a direction different from the first direction X1.

Each of the first active pattern AP1 and the second active pattern AP2 may include silicon (Si) or germanium (Ge), which are elemental semiconductor materials. In examples, each of the first active pattern AP1 and the second active pattern AP2 may include a compound semiconductor, for example, a group IV-IV compound semiconductor or a group III-V compound semiconductor. The group IV-IV compound may be, for example, a binary compound or a binary compound including at least two of carbon (C), silicon (Si), germanium (Ge), and tin (Sn), or a compound formed by doping these elements with a group IV element. The group III-V compound semiconductor may be, for example, one of a binary compound, a ternary compound or a quaternary compound formed by combining at least one of aluminum (Al), gallium (Ga), or indium (In), which are group III elements, with at least one of phosphorus (P), arsenic (As), or antimonium (Sb), which are group V elements.

In some embodiments, each of the first active pattern AP1 and the second active pattern AP2 may include a plurality of bridge patterns 111 to 113 spaced apart from the first side 100a. The bridge patterns 111 to 113 may be arranged in sequence and spaced apart from one another along a vertical direction Z that intersects the first side 100a. The bridge patterns 111 to 113 may be used as channel regions of an MBCFET™ that includes a multi-bridge channel. The number of bridge patterns 111 to 113 included in each of the first active pattern AP1 and the second active pattern AP2 is merely exemplary and is not limited to that shown.

The first gate structure GS1 may be formed on the first side 100a of the first region I. The first gate structure GS1 may intersect the first active pattern AP1. For example, the first gate structure GS1 may be parallel to the first side 100a, and extend long in a third direction Y1 intersecting the first direction X1. In some embodiments, the bridge patterns 111 to 113 of the first active pattern AP1 may extend in the first direction X1 and penetrate the first gate structure GS1.

The second gate structure GS2 may be formed on the first side 100a of the second region II. The second gate structure GS2 may intersect the second active pattern AP2. For example, the second gate structure GS2 may be parallel to the first side 100a and extend long in a fourth direction Y2 intersecting the second direction X2. In some embodiments, the bridge patterns 111 to 113 of the second active pattern AP2 may extend in the second direction X2 and penetrate the second gate structure GS2.

In some embodiments, each of the first gate structure GS1 and the second gate structure GS2 may include a gate dielectric film 120, a gate electrode 130, a gate spacer 140, and a gate capping film 150.

The gate dielectric film 120 may be stacked on the semiconductor substrate 100, the first active pattern AP1, and the second active pattern AP2. The gate dielectric film 120 may be interposed between the semiconductor substrate 100 and the gate electrode 130, between the first active pattern AP1 and the gate electrode 130, and between the second active pattern AP2 and the gate electrode 130.

The gate dielectric film 120 may include a dielectric material, for example, at least one of silicon oxide, silicon oxynitride, silicon nitride or a high dielectric constant material having a higher dielectric constant than silicon oxide. For example, the high dielectric constant material may include, but is not limited to, at least one of hafnium oxide (HfO₂), zirconium oxide (ZrO₂), lanthanum oxide (La₂O₃), aluminum oxide (Al₂O₃), titanium oxide (TiO₂), strontium titanium oxide (SrTiO₃), lanthanum aluminum oxide (LaAlO₃), yttrium oxide (Y₂O₃), hafnium oxynitride (HfOₓN_{y}), zirconium oxynitride (ZrOₓN_{y}), lanthanum oxynitride (La₂OₓN_{y}), aluminum oxynitride (Al₂OₓN_{y}), titanium oxynitride (TiOₓN_{y}), strontium titanium oxynitride (SrTiOₓN_{y}), lanthanum aluminum oxynitride (LaAlOₓN_{y}), yttrium oxynitride (Y₂OₓN_{y}) or combinations thereof.

The gate electrode 130 may intersect the first active pattern AP1 and the second active pattern AP2. Each of the bridge patterns 111 to 113 of the first active pattern AP1 may extend in the first direction X1 and penetrate the gate electrode 130 of the first gate structure GS1. Each of the bridge patterns 111 to 113 of the second active pattern AP2 may extend in the second direction X2 and penetrate the gate electrode 130 of the second gate structure GS2.

The gate electrode 130 may include a conductive material, for example, but is not limited to, at least one of TiN, WN, TaN, Ru, TiC, TaC, Ti, Ag, Al, TiAl, TiAlN, TiAlC, TaCN, TaSiN, Mn, Zr, W, Al, or combinations thereof. The gate electrode 130 may be formed by, but is not limited to, a replacement process.

Although the gate electrode 130 is shown as being a single film, this is merely exemplary, and it is a matter of course that the gate electrode 130 may be a multi-layer film formed by stacking a plurality of conductive films. The gate electrode 130 may include, for example, a work function adjustment film for adjusting a work function, and a filling conductive film that fills a space formed by the work function adjustment film. The work function adjustment film may include, for example, at least one of TiN, TaN, TiC, TaC, TiAlC, or combinations thereof. The filling conductive film may include, for example, W or Al.

The gate spacer 140 may extend along the side face of the gate electrode 130. Each of the bridge patterns 111 to 113 of the first active pattern AP1 may extend in the first direction X1, and penetrate the gate spacer 140 of the first gate structure GS1. Each of the bridge patterns 111 to 113 of the second active pattern AP2 may extend in the second direction X2 and penetrate the gate spacer 140 of the second gate structure GS2. The gate spacer 140 may include an insulating material, for example, but is not limited to, at least one of silicon oxide, silicon nitride, silicon oxynitride, silicon oxycarbide, silicon boron nitride, silicon boron carbonitride, silicon oxycarbon nitride, or combinations thereof.

The gate capping film 150 may extend along the upper side of the gate electrode 130. The gate capping film 150 may include an insulating material, for example, but is not limited to, at least one of silicon oxide, silicon nitride, silicon oxynitride, silicon oxycarbide, silicon boron nitride, silicon boron carbonitride, silicon oxycarbon nitride, or combinations thereof.

In some embodiments, each of the first gate structure GS1 and the second gate structure GS2 may further include an inner spacer 145. The inner spacer 145 may be formed on the side face of the gate electrode 130 between the bridge patterns 111 to 113. The inner spacer 145 may be formed on the side face of the gate electrode 130 between the fin pattern 110 and the bridge patterns 111 to 113. The inner spacer 145 may include an insulating material, for example, but is not limited to, at least one of silicon oxide, silicon nitride, silicon oxynitride, silicon oxycarbide, silicon boron nitride, silicon boron carbonitride, silicon oxycarbon nitride, or combinations thereof. In some embodiments, the inner spacer 145 may be omitted.

The first source/drain region SD1 may be formed on the first side 100a of the first region I. The first source/drain region SD1 may be formed on at least one side face (e.g., both side faces) of the first gate structure GS1. The first source/drain region SD1 may be connected to the first active pattern AP1. For example, each of the bridge patterns 111 to 113 of the first active pattern AP1 may penetrate the first gate structure GS1, and be connected to the first source/drain region SD1. The first source/drain region SD1 may be separated from the gate electrode 130 of the first gate structure GS1 by the gate dielectric film 120, the gate spacer 140 and/or the inner spacer 145.

In some embodiments, the first source/drain region SD1 may include an epitaxial layer. For example, the first source/drain region SD1 may include an epitaxial pattern that is grown from the semiconductor substrate 100 and/or the first active pattern AP1 of the first region I by an epitaxial growth method.

The second source/drain region SD2 may be formed on the first side 100a of the second region II. The second source/drain region SD2 may be formed on at least one side face (e.g., both side faces) of the second gate structure GS2. The second source/drain region SD2 may be connected to the second active pattern AP2. For example, each of the bridge patterns 111 to 113 of the second active pattern AP2 may penetrate the second gate structure GS2, and be connected to the second source/drain region SD2. The second source/drain region SD2 may be separated from the gate electrode 130 of the second gate structure GS2 by the gate dielectric film 120, the gate spacer 140 and/or the inner spacer 145.

In some embodiments, the second source/drain region SD2 may include an epitaxial layer. For example, the second source/drain region SD2 may include an epitaxial pattern that is grown from the semiconductor substrate 100 and/or the second active pattern AP2 of the second region II by an epitaxial growth method.

The first source/drain region SD1 and the second source/drain region SD2 may have the same conductivity type or different conductivity types. When the first source/drain region SD1 and/or the second source/drain region SD2 are provided as source/drain regions of an NFET, each of the first source/drain region SD1 and/or the second source/drain region SD2 may include an N-type impurity (e.g., P, Sb, or As) or an impurity for preventing diffusion of the N-type impurity. When the first source/drain region SD1 and/or the second source/drain region SD2 are provided as source/drain regions of a PFET, each of the first source/drain region SD1 and/or the second source/drain region SD2 may include a P-type impurity (e.g., B, In, Ga or Al) or an impurity for preventing diffusion of the P-type impurity.

The first interlayer insulating film 190 may fill the space on the side face of the first gate structure GS1 and the side face of the second gate structure GS2. The first interlayer insulating film 190 may cover the first source/drain region SD1 and the second source/drain region SD2. The second interlayer insulating film 192 may be formed on the first gate structure GS1, the second gate structure GS2, and the first interlayer insulating film 190. The third interlayer insulating film 194 may be formed on the second interlayer insulating film 192.

The first interlayer insulating film 190, the second interlayer insulating film 192, and the third interlayer insulating film 194 may include at least one of, for example, silicon oxide, silicon nitride, silicon oxynitride, silicon oxycarbide, silicon boron nitride, silicon boron carbonitride, silicon oxycarbon nitride, or a low dielectric constant material having a dielectric constant smaller than that of silicon oxide. The low dielectric constant material may include, for example, but is not limited to, at least one of FOX (Flowable Oxide), TOSZ (Torene SilaZene), USG (Undoped Silica Glass), BSG (Borosilica Glass), PSG (PhosphoSilica Glass), BPSG (BoroPhosphoSilica Glass), PETEOS (Plasma Enhanced Tetra Ethyl Ortho Silicate), FSG (Fluoride Silicate Glass), CDO (Carbon Doped silicon Oxide), Xerogel, Aerogel, Amorphous Fluorinated Carbon, OSG (Organo Silicate Glass), Parylene, BCB (bis-benzocyclobutenes), SiLK, polyimide, porous polymeric material, or combinations thereof.

The first source/drain contact FCA1 may be formed on the upper side of the first source/drain region SD1. The first source/drain contact FCA1 may be connected to the first source/drain region SD1. For example, the first source/drain contact FCA1 may penetrate the first interlayer insulating film 190 and the second interlayer insulating film 192, and come into contact with the upper side of the first source/drain region SD1.

The second source/drain contact FCA2 may be formed on the upper side of the second source/drain region SD2. The second source/drain contact FCA2 may be connected to the second source/drain region SD2. For example, the second source/drain contact FCA2 may penetrate the first interlayer insulating film 190 and the second interlayer insulating film 192, and come into contact with the upper side of the second source/drain region SD2.

The first gate contact FCB1 may be formed on the upper side of the first gate structure GS1. The first gate contact FCB1 may be connected to the gate electrode 130 of the first gate structure GS1. For example, the first gate contact FCB1 may penetrate the gate capping film 150, the second interlayer insulating film 192, and the third interlayer insulating film 194 of the first gate structure GS1, and come into contact with the upper side of the gate electrode 130 of the first gate structure GS1.

The second gate contact FCB2 may be formed on the upper side of the second gate structure GS2. The second gate contact FCB2 may be connected to the gate electrode 130 of the second gate structure GS2. For example, the second gate contact FCB2 may penetrate the gate capping film 150, the second interlayer insulating film 192, and the third interlayer insulating film 194 of the second gate structure GS2, and come into contact with the upper side of the gate electrode 130 of the second gate structure GS2.

The through via TV may extend in the vertical direction Z. The through via TV may penetrate the semiconductor substrate 100 of the second region II. For example, a field insulating film 105 that covers at least a part of a side face of the semiconductor substrate 100 of the second region II may be formed. The through via TV may extend in the vertical direction Z, and penetrate the field insulating film 105, the first interlayer insulating film 190, the second interlayer insulating film 192, and the third interlayer insulating film 194.

Each of the first source/drain contact FCA1, the first gate contact FCB1, the second source/drain contact FCA2, the second gate contact FCB2 and the through via TV may include at least one of a conductive material, for example, but is not limited to, at least one of a metal such as cobalt (Co), titanium (Ti), tantalum (Ta), ruthenium (Ru), tungsten (W) or cobalt tungsten phosphide (CoWP); a conductive metal nitride such as titanium nitride (TiN), tantalum nitride (TaN) or tungsten nitride (WN); and/or a silicide such as nickel silicide (NiSi), cobalt silicide (CoSi), tungsten silicide (WSi), titanium silicide (TiSi), niobium silicide (NbSi) or tantalum silicide (TaSi).

The front wiring structure FW may be formed on the first side 100a of the first region I and the second region II. For example, the front wiring structure FW may be formed on the third interlayer insulating film 194. The front wiring structure FW may include a front inter-wiring insulating film 210, front wiring patterns F1 to F3, and front via patterns FV. The front wiring patterns F1 to F3 may form a multi-layer wiring structure in the front inter-wiring insulating film 210. The front via patterns FV may interconnect the front wiring patterns F1 to F3 in the vertical direction Z. The number of layers, number, placement and the like of the front inter-wiring insulating film 210, the front wiring patterns F1 to F3 and the front via patterns FV are merely exemplary, and are not limited to those shown in the drawings.

The front wiring structure FW may be electrically connected to the first source/drain region SD1, the first gate structure GS1, the second source/drain region SD2, and/or the second gate structure GS2. For example, the front wiring patterns F1 to F3 and/or the front via patterns FV may be electrically connected to the first source/drain contact FCA1, the first gate contact FCB1, the second source/drain contact FCA2, and/or the second gate contact FCB2.

In some embodiments, a first via contact 195 which penetrates the third interlayer insulating film 194 may be formed. Each of the first source/drain contact FCA1 and/or the second source/drain contact FCA2 may be connected to one of the lower front wiring patterns F1 through the first via contact 195.

In some embodiments, each of the first gate contact FCB1 and/or the second gate contact FCB2 may be connected to a corresponding lower front wiring pattern F1.

In some embodiments, the front wiring structure FW may provide a power delivery network of the second region II. For example, the front wiring patterns F1 to F3 of the second region II may include a first front wiring pattern 221. The first front wiring pattern 221 may be connected to the second source/drain region SD2. The first front wiring pattern 221 may be provided as a power supply wiring to which a power supply voltage (e.g., V_{DD} or V_{SS}) is applied. Thus, the first front wiring pattern 221 may form a frontside power delivery network (FSPDN) that provides the power supply voltage to the semiconductor device of the second region II on the first side 100a of the second region II.

In some embodiments, the front wiring structure FW of the second region II may be connected to the through via TV. For example, the through via TV may be connected to the first frontside wiring pattern 221. The first frontside wiring pattern 221 may electrically connect the second source/drain region SD2 and the through via TV.

The back source/drain contact BCA may be formed on the lower side of the first source/drain region SD1. The back source/drain contact BCA may be connected to the first source/drain region SD1. In some embodiments, a first height D11 of the back source/drain contact BCA in the vertical direction Z may be equal to or greater than a first distance H1 by which the first source/drain region SD1 is spaced apart from the second side 100b of the first region I in the vertical direction Z. The back source/drain contact BCA may penetrate the semiconductor substrate 100 of the first region I, and come into contact the lower side of the first source/drain region SD1.

The back gate contact BCB may be formed on the lower side of the first gate structure GS1. The back gate contact BCB may be connected to the gate electrode 130 of the first gate structure GS1. In some embodiments, a second height D21 of the back gate contact BCB in the vertical direction Z may be greater than the first thickness T1 of the semiconductor substrate 100 of the first region I. The back gate contact BCB may penetrate the semiconductor substrate 100 of the first region I and the gate dielectric film 120 of the first gate structure GS1, and come into contact with the lower side of the gate electrode 130 of the first gate structure GS1.

For example, the back gate contact BCB may penetrate the semiconductor substrate 100 of the first region I, and come into contact with the lower side of the gate electrode 130 of the first gate structure GS1. In some embodiments, the back gate contact BCB may be omitted.

The back source/drain contact BCA and the back gate contact BCB may each include a conductive material, for example, but is not limited to, at least one of a metal such as cobalt (Co), titanium (Ti), tantalum (Ta), ruthenium (Ru), tungsten (W) or cobalt tungsten phosphide (CoWP); a conductive metal nitride such as titanium nitride (TiN), tantalum nitride (TaN) or tungsten nitride (WN); and/or a silicide such as nickel silicide (NiSi), cobalt silicide (CoSi), tungsten silicide (WSi), titanium silicide (TiSi), niobium silicide (NbSi), or tantalum silicide (TaSi).

The back insulating film 300 may be formed on the second side 100b of the semiconductor substrate 100 of the first region I. Although the thickness of the back insulating film 300 is shown as being the same as a difference between the first thickness T1 and the second thickness T2, this is merely exemplary. Unlike the shown example, the thickness of the back insulating film 300 may be greater or smaller than the difference between the first thickness T1 and the second thickness T2.

The back insulating film 300 may include, for example, but is not limited to, at least one of silicon oxide, silicon nitride, silicon oxynitride, silicon oxycarbide, silicon boron nitride, silicon boron carbonitride, silicon oxycarbon nitride, or a low dielectric constant material having a dielectric constant smaller than that of silicon oxide

The first contact pattern CP1 may be formed in the semiconductor substrate 100 of the second region II. The first contact pattern CP1 may be connected to the semiconductor substrate 100 of the second region II. The first contact pattern CP1 may come into contact with the second side 100b. For example, the first contact pattern CP1 may extend from the second side 100b toward the first side 100a in the vertical direction Z.

In some embodiments, the first contact pattern CP1 may be spaced apart from the first side 100a. For example, the third height D12 of the first contact pattern CP1 in the vertical direction Z may be smaller than the second thickness T2 of the semiconductor substrate 100 of the second region II.

In some embodiments, the first contact pattern CP1 may be formed at the same level as the back source/drain contact BCA. In this specification, the expression “the same level” means formation by the same fabricating process. For example, the back source/drain contact BCA and the first contact pattern CP1 may include the same material or have the same material composition.

In some embodiments, the first contact pattern CP1 may overlap the second source/drain region SD2 in the vertical direction Z. The first contact pattern CP1 may be spaced apart from the second source/drain region SD2 in the vertical direction Z.

In some embodiments, the third height D12 of the first contact pattern CP1 may be smaller than the first height D11 of the back source/drain contact BCA. This may be due to the difference in thickness between the semiconductor substrate 100 of the first region I and the semiconductor substrate 100 of the second region II in the etching process for forming the back source/drain contact BCA and the first contact pattern CP1.

The back wiring structure BW may be formed on the second side 100b of the first region I and the second region II. For example, the back wiring structure BW may be formed under the back insulating film 300 and the semiconductor substrate 100 of the second region II. The back wiring structure BW may include a back inter-wiring insulating film 310, back wiring patterns B1 to B3, and back via patterns BV. The back wiring patterns B1 to B3 may form a multi-layer wiring structure in the back inter-wiring insulating film 310. The back via patterns BV may interconnect the back wiring patterns B1 to B3 in the vertical direction Z. The number of layers, the number, placement and the like of the back surface inter-wiring insulating film 310, the back surface wiring patterns B1 to B3, and the back surface via patterns BV are merely exemplary, and are not limited to those shown in the drawings.

The back wiring structure BW may be electrically connected to the first source/drain region SD1 and/or the first gate structure GS1. For example, the back wiring patterns B1 to B3 and/or the back via patterns BV may be electrically connected to the back source/drain contact BCA and/or the back gate contact BCB.

In some embodiments, a second via contact 305 which penetrates the back insulating film 300 may be formed. The back source/drain contact BCA and/or the back gate contact BCB may each be connected to one of the lower back wiring patterns B1 through the second via contact 305.

In some embodiments, the back wiring structure BW may provide a power delivery network of the first region I. For example, the back wiring patterns B1 to B3 of the first region I may include a first back wiring pattern 321. The first back wiring pattern 321 may be connected to the first source/drain region SD1. The first back wiring pattern 321 may be provided as a power supply wiring to which a power supply voltage (e.g., V_{DD} or V_{SS}) is applied. Accordingly, the first back wiring pattern 321 may form a backside power delivery network (BSPDN) that provides a power supply voltage to the semiconductor device of the first region I on the second side 100b of the first region I.

In some embodiments, the back wiring structure BW may be connected to the through via TV. For example, the back wiring patterns B1 to B3 of the second region II may include a second back wiring pattern 322. The second back wiring pattern 322 may be connected to the through via TV. The through via TV may extend in the vertical direction Z to electrically connect the first front wiring pattern 221 and the second back wiring pattern 322. Although the second back wiring pattern 322 is shown as being in contact with the through via TV, this is merely exemplary. Unlike the shown example, some of the back via patterns BV may be interposed between the through via TV and the second back wiring pattern 322.

The back wiring structure BW may be connected to the first contact pattern CP1. For example, the back wiring patterns B1 to B3 of the second region II may include a third back wiring pattern 323. The third back wiring pattern 323 may be connected to the first contact pattern CP1. Although the third back wiring pattern 323 is shown as being in contact with the first contact pattern CP1, this is merely exemplary. Unlike the shown example, some of the back via patterns BV may be interposed between the first contact pattern CP1 and the third back wiring pattern 323.

The third back wiring pattern 323 may not provide a power delivery network of the second region II. For example, the third back wiring pattern 323 may be electrically separated from the first back wiring pattern 321 and the second back wiring pattern 322 that provide the power delivery network.

In some embodiments, the first contact pattern CP1 and the third back wiring pattern 323 may electrically float.

The connection terminal 390 may be formed on the second side 100b of the first region I and the second region II. For example, the connection terminal 390 may be formed under the back inter-wiring insulating film 310. The connection terminal 390 may be electrically connected to the back wiring structure BW. For example, the connection terminal 390 may be connected to the upper back wiring patterns B3 through some of the back via pattern BV. There may be more than one connection terminal 390, including a first connection terminal, a second connection terminal, etc . . .

The connection terminal 390 may be, for example, but is not limited to, a solder ball, a bump or the like. The semiconductor device of the first region I and the semiconductor device of the second region II may be electrically connected to an external electronic device or the like through the connection terminal 390. For example, a power supply voltage (e.g., V_{DD} or V_{SS}) may be applied to the first source/drain region SD1 through the connection terminal 390, the first back wiring pattern 321, and the back source/drain contact BCA of the first region I. For example, the power supply voltage (e.g., V_{DD} or V_{SS}) may be applied to the second source/drain region SD2 through the connection terminal 390, the second back wiring pattern 322, the through via TV, the first front wiring pattern 221 and the second source/drain contact FCA2 of the second region II.

To reduce the voltage drop (e.g., IR drop) of the power delivery network (PDN) associated with the high integration of the semiconductor device, a so-called backside power delivery network (BSPDN) that provides a power delivery network onto the backside of a semiconductor substrate has been researched. As the process for the backside power delivery network develops, the thickness of the semiconductor substrate continues to decrease, which causes a decrease in the detection power of failure analysis such as PVC (Passive Voltage Contrast). For example, in a semiconductor chip that includes the backside power delivery network, some regions such as the core region (hereinafter, a FSPDN region) may still use the frontside power delivery network. However, as the thickness of the semiconductor substrate decreases (e.g., to 100 nm or less, or 70 nm or less) by a thinning process on the backside of the semiconductor substrate, the amount of electrons supplied from the semiconductor substrate decreases, and the PVC sensitivity to the FSPDN region decreases.

In contrast, the semiconductor device according to some embodiments may improve the PVC sensitivity to the FSPDN region, using the first contact pattern CP1 and a back wiring structure BW connected to the first contact pattern CP1. Specifically, as mentioned above, the first contact pattern CP1 may be connected to the semiconductor substrate 100 of the second region II provided as the FSPDN region, and the back wiring structure BW of the second region II may include a third back wiring pattern 323 connected to the first contact pattern CP1. The first contact pattern CP1 and the third back wiring pattern 323 may compensate for the second thickness T2 the semiconductor substrate 100 of the second region II (for example, reduced to 100 nm or less or 70 nm or less), and supply an additional amount of electrons to the semiconductor substrate 100 of the second region II. Accordingly, the PVC sensitivity to the FSPDN region is improved, and a semiconductor device that is easy to analyze defects may be provided. The thickness of a layer may refer to the dimension in the direction perpendicular to the surface of the layer. The direction perpendicular to the surface may refer to its average orientation and not include minor unintentional deviations (e.g., pits) that may be formed during a manufacturing process.

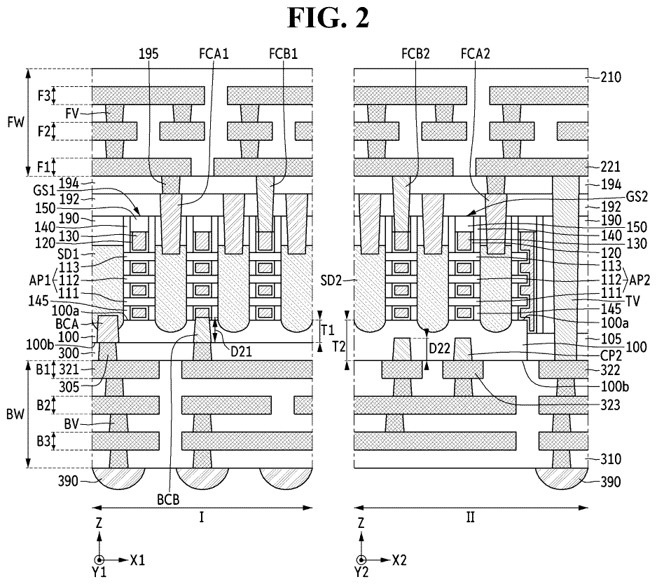

FIG. 2 is a schematic cross-sectional view for explaining a semiconductor device according to some embodiments. For convenience of explanation, repeated parts of contents explained above using FIG. 1 may be the same as described herein, and will be briefly explained or omitted.

Referring to FIG. 2, the semiconductor device according to some embodiments includes a second contact pattern CP2.

The second contact pattern CP2 may be formed in the semiconductor substrate 100 of the second region II. The second contact pattern CP2 may be connected to the semiconductor substrate 100 of the second region II. The second contact pattern CP2 may come into contact with the second side 100b. For example, the second contact pattern CP2 may extend from the second side 100b toward the first side 100a in the vertical direction Z.

In some embodiments, the second contact pattern CP2 may be formed at the same level as the back gate contact BCB. For example, the back gate contact BCB and the second contact pattern CP2 may include the same material or have the same material composition.

In some embodiments, the second contact pattern CP2 may overlap the second gate structure GS2 in the vertical direction Z. The second contact pattern CP2 may be spaced apart from the second gate structure GS2 in the vertical direction Z.

In some embodiments, a fourth height D22 of the second contact pattern CP2 may be smaller than the second height D21 of the back gate contact BCB. This may be due to a difference in thickness between the semiconductor substrate 100 of the first region I and the semiconductor substrate 100 of the second region II in the etching process for forming the back gate contact BCB and the second contact pattern CP2.

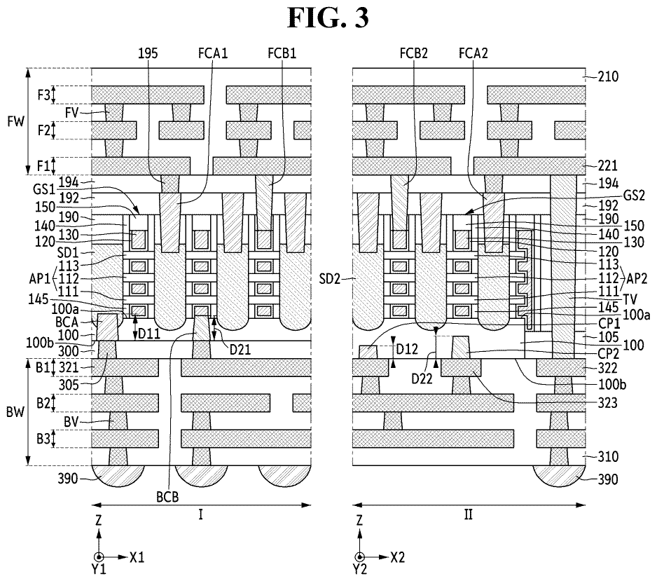

FIG. 3 is a schematic cross-sectional view for explaining a semiconductor device according to some embodiments. For convenience of explanation, repeated parts of contents explained above using FIGS. 1 and 2 may be the same as described herein and will be briefly described or omitted.

Referring to FIG. 3, the semiconductor device according to some embodiments includes both a first contact pattern CP1 and a second contact pattern CP2.

Because the first contact pattern CP1 may be the same as that explained above using FIG. 1, and the second contact pattern CP2 may be the same as that explained above using FIG. 2, detailed description thereof will not be provided below.

In some embodiments, the first contact pattern CP1 and the second contact pattern CP2 may be electrically connected. For example, the first contact pattern CP1 and the second contact pattern CP2 may be electrically connected through the back wiring patterns B1 to B3 and the back via patterns BV.

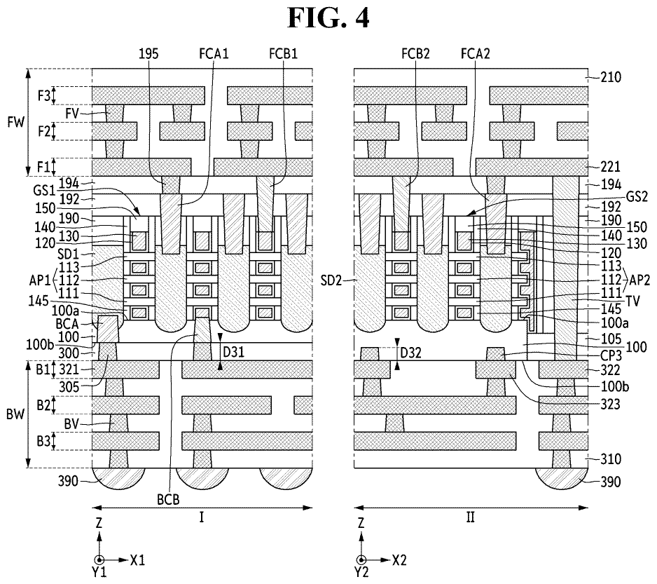

FIG. 4 is a schematic cross-sectional view for explaining a semiconductor device according to some embodiments. For convenience of explanation, repeated parts of contents explained above using FIGS. 1 to 3 may be the same as described herein and will be briefly explained or omitted.

Referring to FIG. 4, the semiconductor device according to some embodiments includes a third contact pattern CP3.

The third contact pattern CP3 may be formed in the semiconductor substrate 100 of the second region II. The third contact pattern CP3 may be connected to the semiconductor substrate 100 of the second region II. The third contact pattern CP3 may come into contact with the second side 100b. For example, the third contact pattern CP3 may extend from the second side 100b toward the first side 100a in the vertical direction Z.

In some embodiments, the third contact pattern CP3 may be formed at the same level as the second via contact 305. For example, the second via contact 305 and the third contact pattern CP3 may include the same material as each other or have the same material composition as each other.

Although the third contact pattern CP3 is shown to overlap the second source/drain region SD2 in the vertical direction Z, this is merely exemplary. Unlike the shown example, the third contact pattern CP3 may overlap the second gate structure GS2 in the vertical direction Z. The third contact pattern CP3 may be spaced apart from the second source/drain region SD2 and/or the second gate structure GS2 in the vertical direction Z.

In some embodiments, a fifth height D31 of the second via contact 305 in the vertical direction Z may be different from a sixth height D32 of the third contact pattern CP3 in the vertical direction Z. For example, as shown, the fifth height D31 may be greater than the sixth height D32. This is due to the difference in the etching selectivity between the back insulating film 300 and the semiconductor substrate 100 in the etching process for forming the second via contact 305 and the third contact pattern CP3.

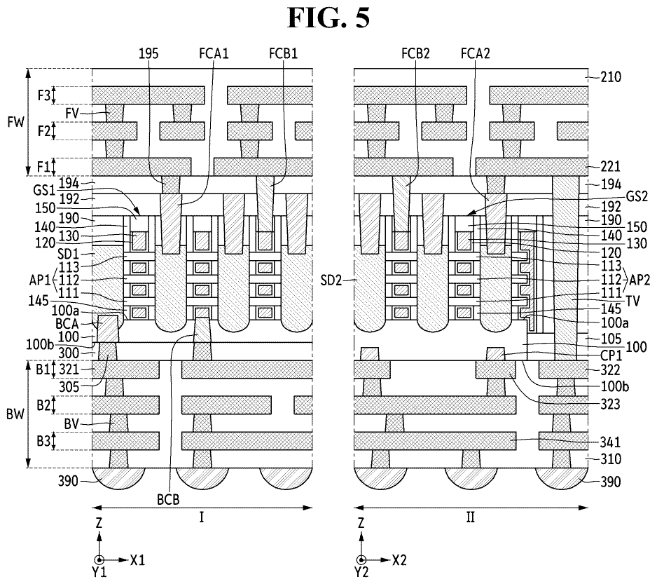

FIG. 5 is a schematic cross-sectional view for explaining a semiconductor device according to some embodiments. For convenience of explanation, repeated parts of contents explained above using FIGS. 1 to 4 may be the same as described herein and will be briefly explained or omitted.

Referring to FIG. 5, in the semiconductor device according to some embodiments, the first contact pattern CP1 is electrically connected to the connection terminal 390.

For example, the upper back wiring patterns B3 of the second region II may include a fourth back wiring pattern 341 electrically connected to the third back wiring pattern 323. Some of the back via patterns BV may connect a part of the connection terminal 390 to the fourth back wiring pattern 341. A predetermined bias voltage (e.g., a ground voltage or a negative (−) voltage) may be applied to the semiconductor substrate 100 of the second region II from an external electronic device or the like through the connection terminal 390. For example, a predetermined bias voltage may be applied to the semiconductor substrate 100 of the second region II through the connection terminal 390, the fourth back wiring pattern 341, the third back wiring pattern 323, and the first contact pattern CP1 of the second region II.

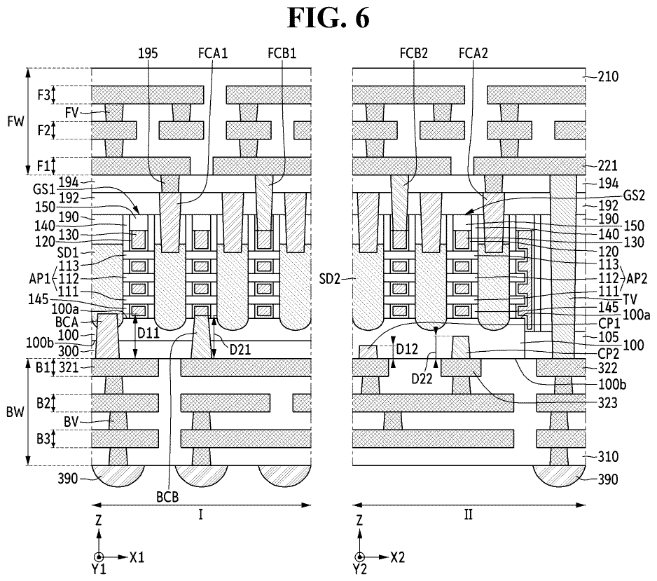

FIG. 6 is a schematic cross-sectional view for explaining a semiconductor device according to some embodiments. For convenience of explanation, repeated parts of contents explained above using FIGS. 1 to 5 may be the same as described herein and will be briefly explained or omitted.

Referring to FIG. 6, in the semiconductor device according to some embodiments, the back source/drain contact BCA and/or the back gate contact BCB penetrate the back insulating film 300 and the semiconductor substrate 100.

For example, the back source/drain contact BCA may penetrate the back insulating film 300 and the semiconductor substrate 100 of the first region I to connect one of the lower back wiring patterns B1 and the first source/drain region SD1.

Alternatively, for example, the back gate contact BCB may penetrate the back insulating film 300, the semiconductor substrate 100 of the first region I, and the gate dielectric film 120 of the first gate structure GS1 to connect the other of the lower back wiring patterns B1 and the gate electrode 130 of the first gate structure GS1.

In some embodiments, the third height D12 of the first contact pattern CP1 in the vertical direction Z may be smaller than the first height D11 of the back source/drain contact BCA in the vertical direction Z.

In some embodiments, the fourth height D22 of the second contact pattern CP2 in the vertical direction Z may be smaller than the second height D21 of the back gate contact BCB in the vertical direction Z.

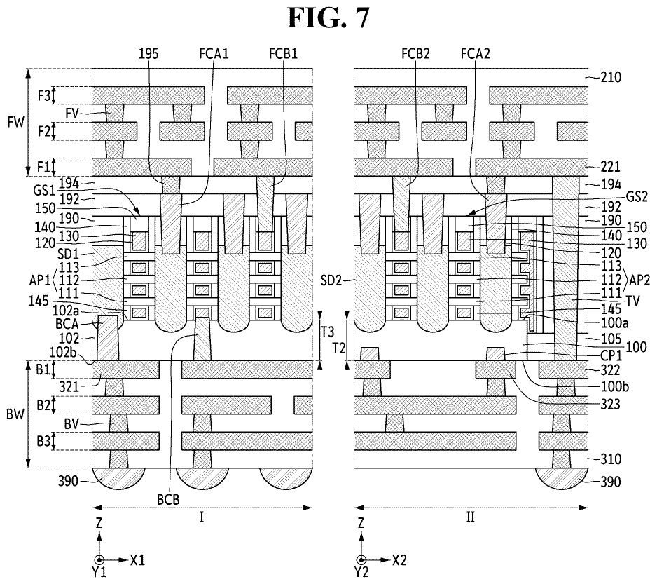

FIG. 7 is a schematic cross-sectional view for explaining a semiconductor device according to some embodiments. For convenience of explanation, repeated parts of contents explained above using FIGS. 1 to 6 may be the same as described herein and will be briefly explained or omitted.

Referring to FIG. 7, a semiconductor device according to some embodiments includes an insulating substrate 102.

The insulating substrate 102 may be disposed in the first region I. The semiconductor substrate 100 may be disposed in the second region II, and may not be disposed in the first region I. The insulating substrate 102 may include, but is not limited to, at least one of silicon oxide, silicon oxynitride, silicon oxycarbon nitride, or combinations thereof. As an example, the insulating substrate 102 may include a silicon oxide film.

The insulating substrate 102 may be interposed between the back wiring structure BW and the first source/drain region SD1 of the first region I, and between the back wiring structure BW and the first gate structure GS1 of the first region I. For example, the insulating substrate 102 may include a third side 102a and a fourth side 102b that are opposite to each other. The first source/drain region SD1 and the first gate structure GS1 may be formed on the third side 102a. The back wiring structure BW of the first region I may be formed on the fourth side 102b.

Although the third thickness T3 of the insulating substrate 102 in the vertical direction Z is shown as being the same as the second thickness T2 of the semiconductor substrate 100 of the second region II in the vertical direction Z, this is merely an example. It goes without saying that the third thickness T3 may be greater or smaller than the second thickness T2, unlike the shown example.

Each of the back source/drain contact BCA and/or the back gate contact BCB may extend in the vertical direction Z and penetrate the insulating substrate 102. For example, the back source/drain contact BCA may penetrate the insulating substrate 102 to connect one of the lower back wiring patterns B1 and the first source/drain region SD1. Alternatively, for example, the back gate contact BCB may penetrate the insulating substrate 102 and the gate dielectric film 120, and connect the other of the lower back wiring patterns B1 and the gate electrode 130 of the first gate structure GS1.

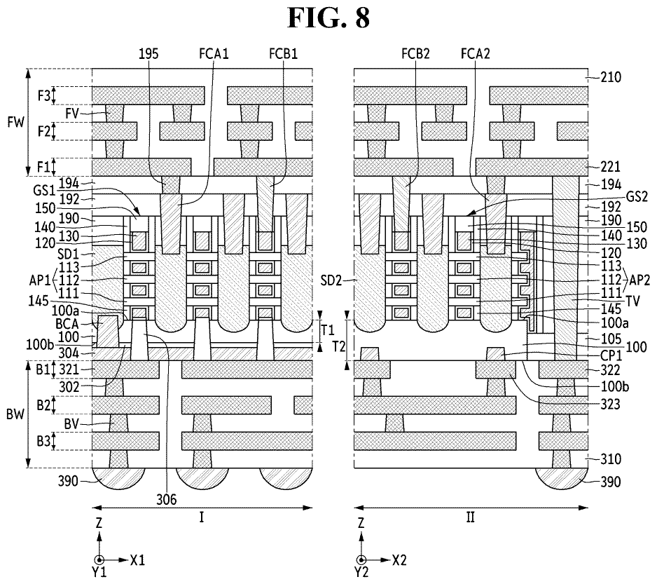

FIG. 8 is a schematic cross-sectional view for explaining a semiconductor device according to some embodiments. For convenience of explanation, repeated parts of contents explained above using FIGS. 1 to 6 may be the same as described herein and will be briefly explained or omitted.

Referring to FIG. 8, the semiconductor device according to some embodiments includes a base insulating film 302, a conductive plate 304, and an isolation insulating pattern 306.

The base insulating film 302 may be formed on the second side 100b of the semiconductor substrate 100 of the first region I. The base insulating film 302 may be interposed between the semiconductor substrate 100 of the first region I and the conductive plate 304. The back source/drain contact BCA may penetrate the base insulating film 302 and the semiconductor substrate 100 of the first region I, and be connected to the first source/drain region SD1.

The conductive plate 304 may be formed under the base insulating film 302. The conductive plate 304 may be interposed between the back source/drain contact BCA and the back wiring structure BW. The back source/drain contact BCA may be electrically connected to the back wiring structure BW through the conductive plate 304. For example, the first back wiring pattern 321 may be connected to the conductive plate 304.

The isolation insulating pattern 306 may be interposed between the first gate structure GS1 and the back wiring structure BW. The isolation insulating pattern 306 may overlap the first gate structure GS1 in the vertical direction Z. The isolation insulating pattern 306 may extend in the vertical direction Z to cut the conductive plate 304, the base insulating film 302, and the semiconductor substrate 100 of the first region I.

The isolation insulating pattern 306 may include, but is not limited to, at least one of silicon nitride, silicon oxynitride, silicon oxycarbide, silicon boron nitride, silicon boron carbonitride, silicon oxycarbon nitride, or combinations thereof.

Hereinafter, a method for fabricating a semiconductor device according to an exemplary embodiment will be described referring to FIGS. 1 to 24.

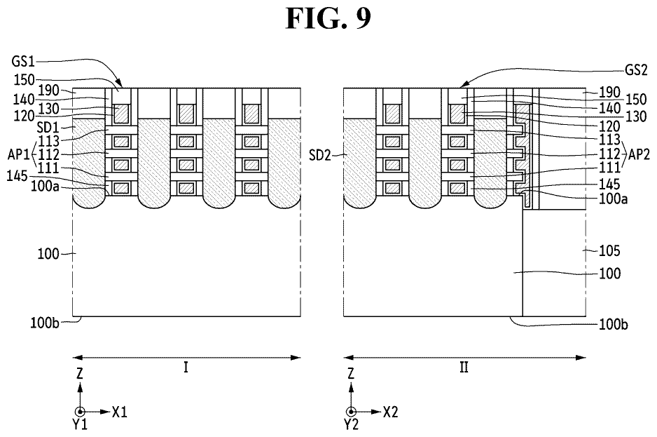

FIGS. 9 to 18 are intermediate step diagrams for explaining a method for fabricating a semiconductor device according to some embodiments. For convenience of description, repeated parts of contents explained above using FIGS. 1 to 8 may be the same as described herein and will be briefly described or omitted.

Referring to FIG. 9, the first active pattern AP1, the second active pattern AP2, the first gate structure GS1, the second gate structure GS2, the first source/drain region SD1, the second source/drain region SD2, and the first interlayer insulating film 190 are formed on the semiconductor substrate 100 and the field insulating film 105.

The first active pattern AP1 may be formed on the first side 100a of the first region I. The second active pattern AP2 may be formed on the first side 100a of the second region II. The first gate structure GS1 may intersect the first active pattern AP1. The second gate structure GS2 may intersect the second active pattern AP2. The first source/drain region SD1 is formed on at least one side face (e.g., both side faces) of the first gate structure GS1, and may be connected to the first active pattern AP1. The second source/drain region SD2 is formed on at least one side face (e.g., both side faces) of the second gate structure GS2, and may be connected to the second active pattern AP2. The first interlayer insulating film 190 may fill spaces on the side face of the first gate structure GS1 and the side face of the second gate structure GS2. The first interlayer insulating film 190 may cover the first source/drain region SD1 and the second source/drain region SD2.

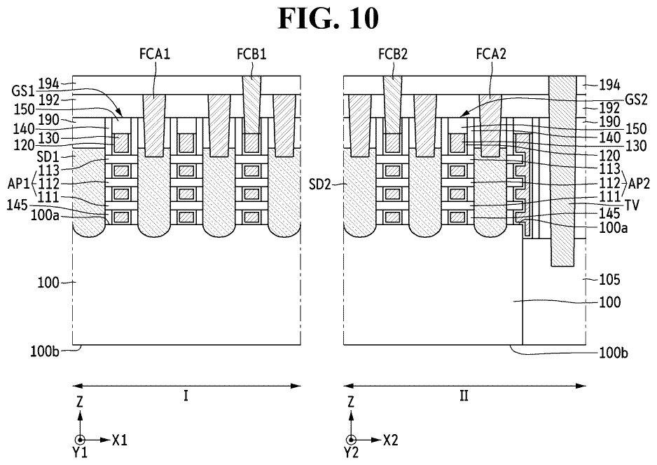

Referring to FIG. 10, the first source/drain contact FCA1, the first gate contact FCB1, the second source/drain contact FCA2, the second gate contact FCB2, and the through via TV are formed.

For example, the second interlayer insulating film 192 may be formed on the first interlayer insulating film 190. The first source/drain contact FCA1 may penetrate the first interlayer insulating film 190 and the second interlayer insulating film 192, and be connected to the first source/drain region SD1. The second source/drain contact FCA2 may penetrate the first interlayer insulating film 190 and the second interlayer insulating film 192, and be connected to the second source/drain region SD2.

Next, the third interlayer insulating film 194 may be formed on the second interlayer insulating film 192. The first gate contact FCB1 may penetrate the gate capping film 150, the second interlayer insulating film 192, and the third interlayer insulating film 194, and be connected to the gate electrode 130 of the first gate structure GS1. The second gate contact FCB2 may penetrate the gate capping film 150, the second interlayer insulating film 192, and the third interlayer insulating film 194, and be connected to the gate electrode 130 of the second gate structure GS2. The through via TV may extend in the vertical direction Z and penetrate the field insulating film 105, the first interlayer insulating film 190, the second interlayer insulating film 192, and the third interlayer insulating film 194.

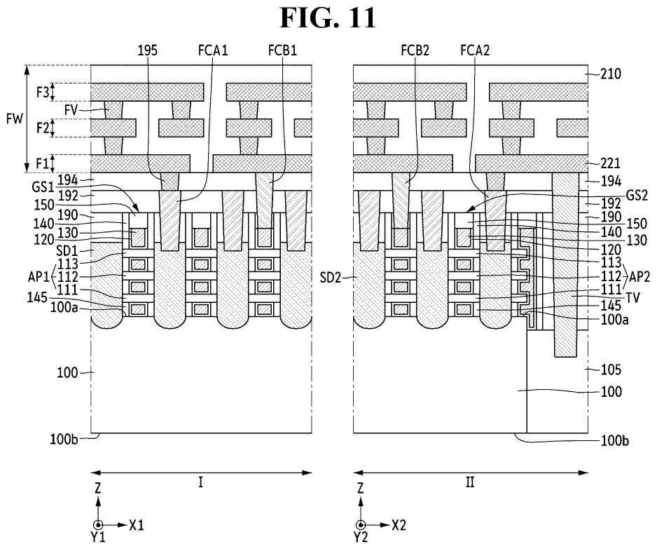

Referring to FIG. 11, a front wiring structure FW is formed.

The front wiring structure FW may be formed on the third interlayer insulating film 194. The front wiring structure FW may be connected to the first source/drain contact FCA1, the first gate contact FCB1, the second source/drain contact FCA2, the second gate contact FCB2, and/or the through via TV.

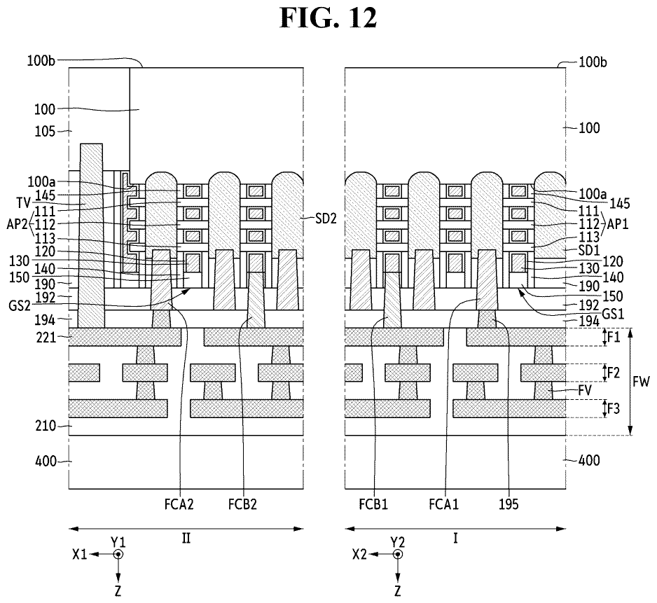

Referring to FIG. 12, the front wiring structure FW is attached onto the carrier substrate 400.

For example, the carrier substrate 400 may be attached to the result of FIG. 11. After the carrier substrate 400 is attached, the result of FIG. 11 may be inverted. For example, as shown in FIG. 12, the second side 100b of the semiconductor substrate 100 may face upward. In some embodiments, the front wiring structure FW may be attached to the carrier substrate 400 by an oxide-oxide bonding process.

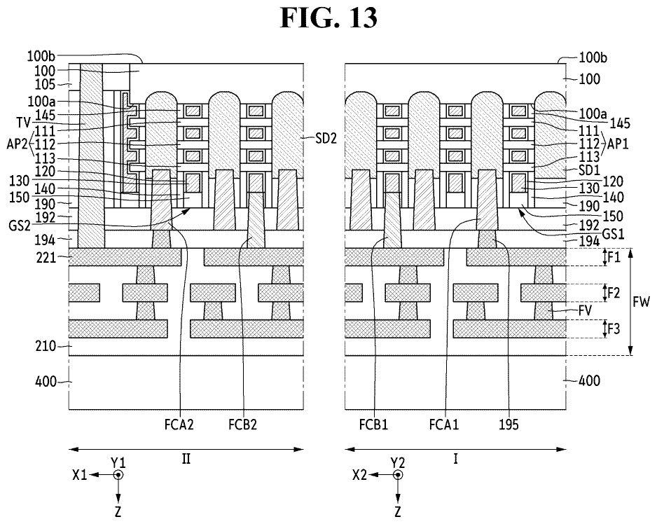

Referring to FIG. 13, a thinning process is performed on the semiconductor substrate 100.

For example, a back grinding process may be performed on the second side 100b of the semiconductor substrate 100. As the thinning process is performed, the thickness of the semiconductor substrate 100 may decrease. In some embodiments, after the thinning process is performed, the thickness of the semiconductor substrate 100 may be about 100 nm or less, or about 70 nm or less. For example, after the thinning process is performed, the thickness of the semiconductor substrate 100 may be about 50 nm to about 70 nm, or about 55 nm to about 65 nm.

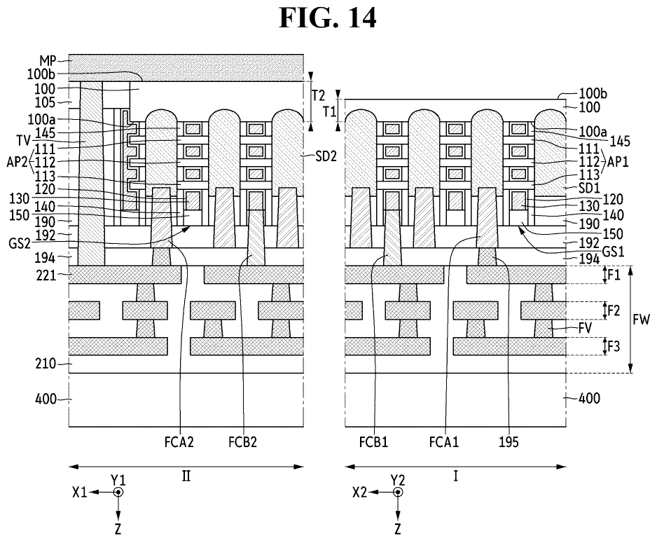

Referring to FIG. 14, a recess process is performed on the semiconductor substrate 100 of the first region I.

For example, a mask pattern MP may be formed on the second side 100b of the semiconductor substrate 100 of the second region II. The mask pattern MP may include, but is not limited to, a photoresist pattern. Next, an etching process may be performed on the second side 100b of the semiconductor substrate 100 of the first region I, by utilizing the mask pattern MP as an etching mask. As the etching process is performed, the first thickness T1 of the semiconductor substrate 100 of the first region I in the vertical direction Z may be smaller than the second thickness T2 of the semiconductor substrate 100 of the second region II in the vertical direction Z. For example, after the etching process is performed, the second thickness T2 may be about 50 nm to about 70 nm, or about 55 nm to about 65 nm, and the first thickness T1 may be about 1 nm to about 40 nm, or about 5 nm to about 35 nm.

After the etching process is performed, the mask pattern MP may be removed.

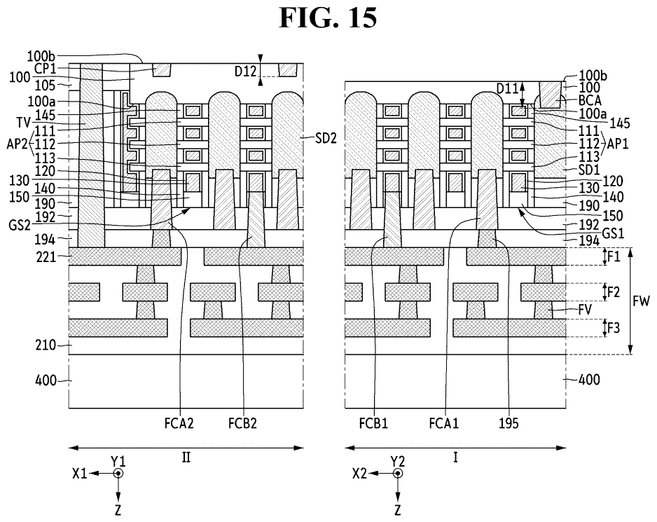

Referring to FIG. 15, the back source/drain contact BCA and the first contact pattern CP1 are formed.

The back source/drain contact BCA may penetrate the semiconductor substrate 100 of the first region I, and be connected to the first source/drain region SD1. The first contact pattern CP1 may be connected to the semiconductor substrate 100 of the second region II.

In some embodiments, the back source/drain contact BCA and the first contact pattern CP1 may be formed at the same level as each other. For example, the back source/drain contact BCA and the first contact pattern CP1 may be formed by the same etching process and the same deposition process. Due to the difference in thickness between the semiconductor substrate 100 of the first region I and the semiconductor substrate 100 of the second region II, the third height D12 of the first contact pattern CP1 may be smaller than the first height D11 of the back source/drain contact BCA.

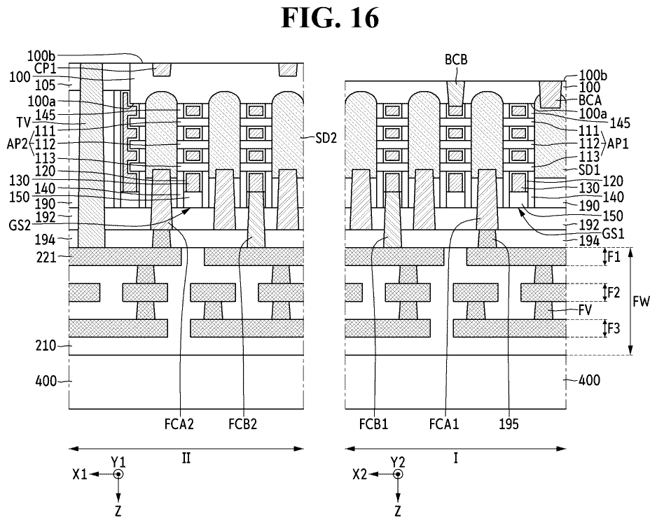

Referring to FIG. 16, the back gate contact BCB is formed.

The back gate contact BCB may penetrate the semiconductor substrate 100 of the first region I and the gate dielectric film 120 of the first gate structure GS1, and be connected to the gate electrode 130 of the first gate structure GS1.

Although the back gate contact BCB is explained as being formed after the back source/drain contact BCA and the first contact pattern CP1 are formed, this is merely exemplary. It goes without saying that the back source/drain contact BCA and the first contact pattern CP1 may be formed after the back gate contact BCB is formed, unlike that explained above with respect to FIGS. 15 and 16.

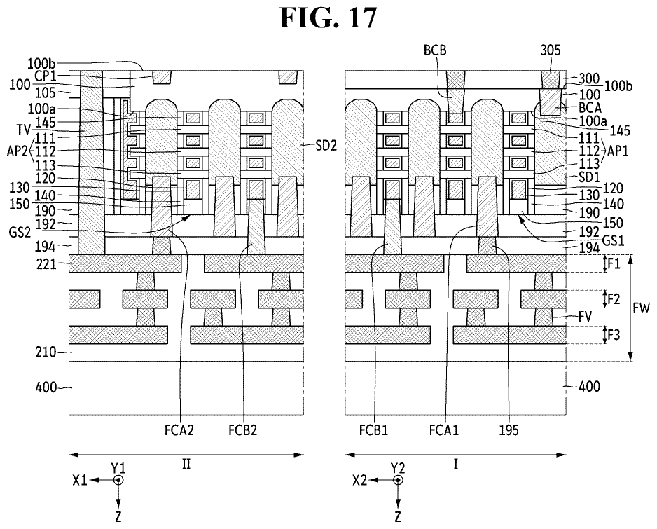

Referring to FIG. 17, the back insulating film 300 and the second via contact 305 are formed.

The back insulating film 300 may be formed on the second side 100b of the semiconductor substrate 100 of the first region I. The second via contact 305 may penetrate the back insulating film 300, and be connected to the back source/drain contact BCA and/or the back gate contact BCB.

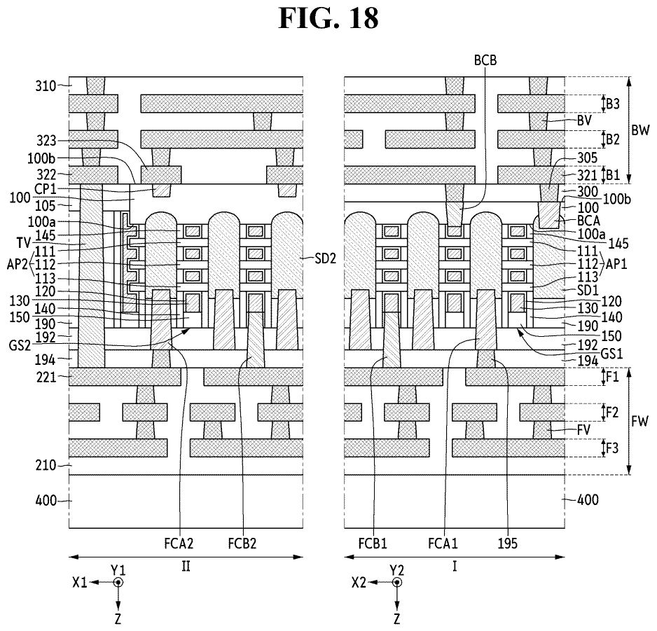

Referring to FIG. 18, the back wiring structure BW is formed.

The back wiring structure BW may be formed on the back insulating film 300 and the semiconductor substrate 100 of the second region II. The back wiring structure BW may be electrically connected to the back source/drain contact BCA, the back gate contact BCB, and/or the first contact pattern CP1.

Next, referring to FIG. 1, the connection terminal 390 is formed on the back wiring structure BW. Accordingly, the semiconductor device explained above using FIG. 1 may be fabricated.

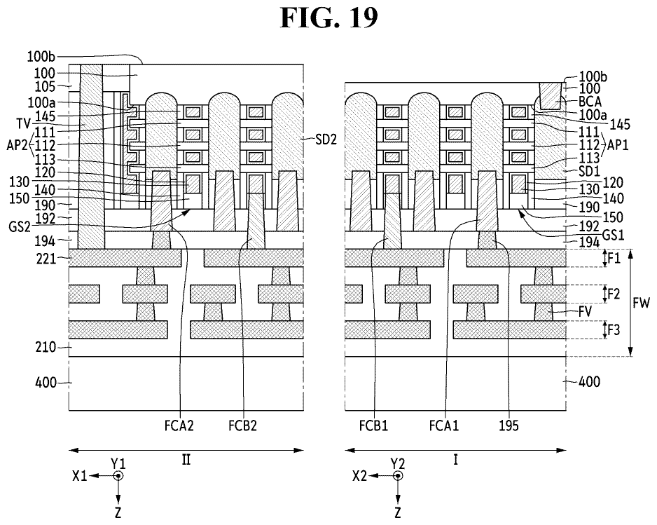

FIGS. 19 to 21 are intermediate step diagrams for explaining a method for fabricating a semiconductor device according to some embodiments. For convenience of explanation, repeated parts of contents explained above using FIGS. 1 to 18 may be the same as described herein and will be briefly explained or omitted. For reference, FIG. 19 is an intermediate step diagram for explaining the process after FIG. 14.

Referring to FIG. 19, the back source/drain contact BCA is formed.

The back source/drain contact BCA may penetrate the semiconductor substrate 100 of the first region I, and be connected to the first source/drain region SD1.

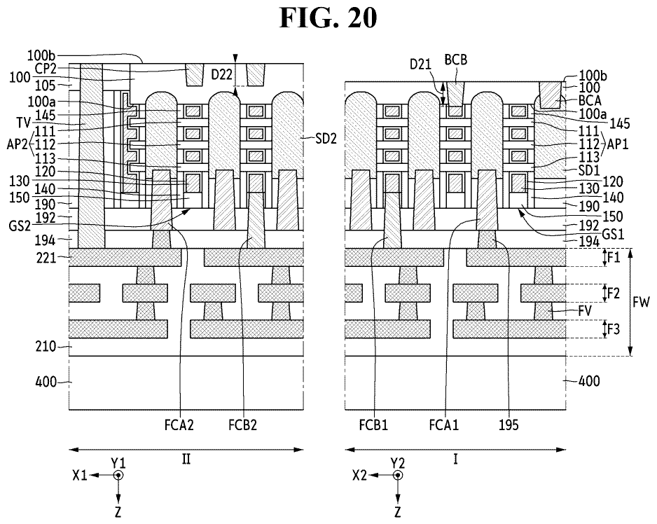

Referring to FIG. 20, the back gate contact BCB and the second contact pattern CP2 are formed.

The back gate contact BCB may penetrate the semiconductor substrate 100 of the first region I and the gate dielectric film 120 of the first gate structure GS1, and be connected to the gate electrode 130 of the first gate structure GS1. The second contact pattern CP2 may be connected to the semiconductor substrate 100 of the second region II.

In some embodiments, the back gate contact BCB and the second contact pattern CP2 may be formed at the same level as each other. For example, the back gate contact BCB and the second contact pattern CP2 may be formed by the same etching process and the same deposition process. Due to the difference in thickness between the semiconductor substrate 100 of the first region I and the semiconductor substrate 100 of the second region II, the fourth height D22 of the second contact pattern CP2 may be smaller than the second height D21 of the back gate contact BCB.

Although the back gate contact BCB and the second contact pattern CP2 are explained as being formed after the back source/drain contact BCA is formed, this is merely exemplary. It goes without saying that the back source/drain contact BCA may be formed after the back gate contact BCB and the second contact pattern CP2 are formed, unlike those explained above with respect to FIGS. 19 and 20.

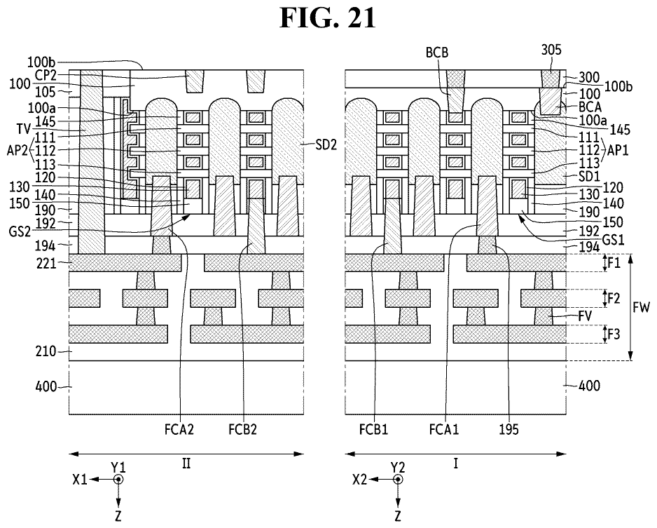

Referring to FIG. 21, the back insulating film 300 and the second via contact 305 are formed. Next, the steps explained above using FIGS. 18 and 1 may be performed. Accordingly, the semiconductor device explained above using FIG. 2 may be fabricated.

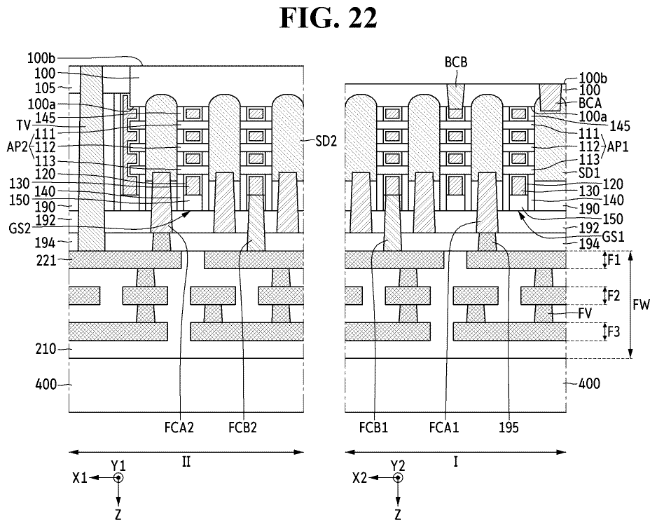

FIGS. 22 to 24 are intermediate step diagrams for explaining a method for fabricating a semiconductor device according to some embodiments. For convenience of explanation, repeated parts of contents explained above using FIGS. 1 to 18 may be the same as described herein and will be briefly explained or omitted. For reference, FIG. 22 is an intermediate step diagram for explaining the step after FIG. 14.

Referring to FIG. 22, the back source/drain contact BCA and the back gate contact BCB are formed.

The back source/drain contact BCA may penetrate the semiconductor substrate 100 of the first region I, and be connected to the first source/drain region SD1. The back gate contact BCB may penetrate the semiconductor substrate 100 of the first region I and the gate dielectric film 120 of the first gate structure GS1, and be connected to the gate electrode 130 of the first gate structure GS1.

The back source/drain contact BCA may be formed after the back gate contact BCB is formed, or may be formed before the back gate contact BCB is formed.

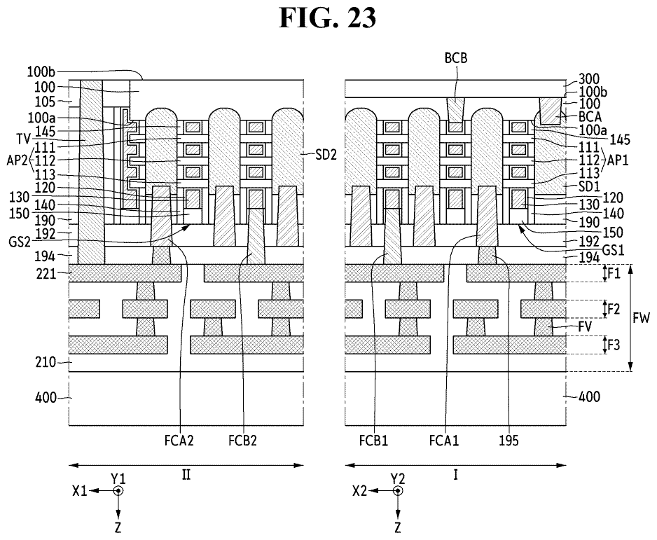

Referring to FIG. 23, the back insulating film 300 is formed.

The back insulating film 300 may be formed on the second side 100b of the semiconductor substrate 100 of the first region I.

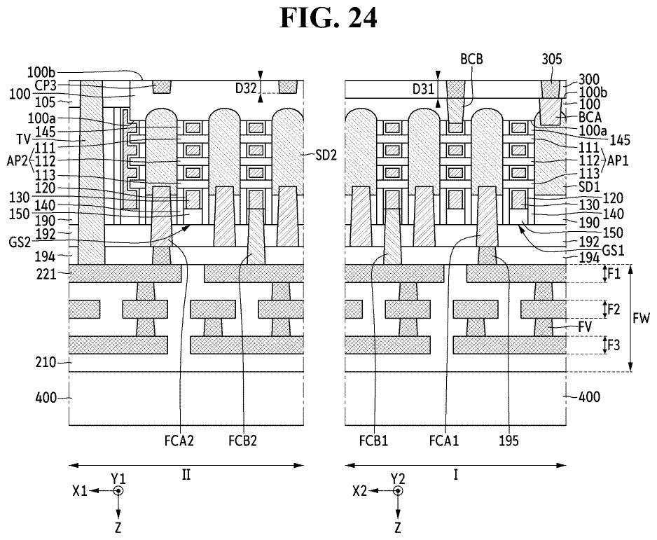

Referring to FIG. 24, the second via contact 305 and the third contact pattern CP3 are formed.

The second via contact 305 may penetrate the back insulating film 300, and be connected to the back source/drain contact BCA and/or the back gate contact BCB. The third contact pattern CP3 may be connected to the semiconductor substrate 100 of the second region II.

In some embodiments, the second via contact 305 and the third contact pattern CP3 may be formed at the same level as each other. For example, the second via contact 305 and the third contact pattern CP3 may be formed by the same etching process and the same deposition process. Due to differences in the etching selectivity between the back insulating film 300 and the semiconductor substrate 100, the fifth height D31 of the second via contact 305 and the sixth height D32 of the third contact pattern CP3 may differ from each other.

While the present inventive concepts have been particularly shown and described with reference to exemplary embodiments thereof, it will be understood by those of ordinary skill in the art that various changes in form and details may be made therein without departing from the spirit and scope of the present inventive concepts as defined by the following claims. It is therefore desired that the present embodiments be considered in all respects as illustrative and not restrictive, reference being made to the appended claims rather than the foregoing description to indicate the scope of the invention.

What is claimed is:

1. A semiconductor device comprising:
a semiconductor substrate including a first side and a second side that is on an opposite side of the semiconductor substrate from the first side;
an active pattern on the first side;
a gate structure that intersects the active pattern;
a source/drain region connected to the active pattern, on a side face of the gate structure;
a front wiring structure connected to at least one of the gate structure or the source/drain region, on the first side;
a back wiring structure on the second side; and
a contact pattern in the semiconductor substrate, wherein the contact pattern is connected to the back wiring structure,
wherein a height of the contact pattern in a vertical direction intersecting the first side is smaller than a thickness of the semiconductor substrate in the vertical direction.

2. The semiconductor device of claim 1,
wherein the front wiring structure includes a power supply wiring configured to have a power supply voltage applied thereto.

3. The semiconductor device of claim 2, further comprising:
a through via that extends in the vertical direction, and is connected to the power supply wiring,
wherein the back wiring structure includes a first back wiring pattern connected to the contact pattern, and a second back wiring pattern connected to the through via, and
the first back wiring pattern and the second back wiring pattern are separated from each other.

4. The semiconductor device of claim 1,
wherein the contact pattern overlaps the source/drain region in the vertical direction.

5. The semiconductor device of claim 4,
wherein the contact pattern is spaced apart from the source/drain region in the vertical direction.

6. The semiconductor device of claim 1,
wherein the contact pattern overlaps the gate structure in the vertical direction.

7. The semiconductor device of claim 6,
wherein the contact pattern is spaced apart from the gate structure in the vertical direction.

8. The semiconductor device of claim 1,
wherein the active pattern includes a plurality of bridge patterns each bridge pattern of the plurality of bridge patterns being spaced apart from the semiconductor substrate in the vertical direction and each bridge pattern penetrating the gate structure.

9. The semiconductor device of claim 1,
wherein the thickness of the semiconductor substrate in the vertical direction is nm or less.

10. The semiconductor device of claim 1,
wherein the contact pattern electrically floats.

11. A semiconductor device comprising:
a semiconductor substrate including a first side and a second side that is on an opposite side of the semiconductor substrate from the first side;
an active pattern on the first side;
a gate structure that intersects the active pattern;
a source/drain region connected to the active pattern, on a side face of the gate structure;
a front wiring structure connected to the source/drain region, on the first side;
a contact pattern in the semiconductor substrate, wherein the contact pattern is spaced apart from the gate structure and from the source/drain region;
a first back wiring pattern connected to the contact pattern, on the second side;
a second back wiring pattern separated from the first back wiring pattern; and
a through via that extends in a vertical direction crossing the first side, and connects the front wiring structure and the second back wiring pattern.

12. The semiconductor device of claim 11,
wherein the source/drain region is configured to have a power supply voltage applied thereto through the second back wiring pattern, the through via, and the front wiring structure.

13. The semiconductor device of claim 11, further comprising:
a back inter-wiring insulating film that covers the first back wiring pattern and the second back wiring pattern, on the second side; and
a first connection terminal connected to the second back wiring pattern below the back inter-wiring insulating film.

14. The semiconductor device of claim 13, further comprising:
a second connection terminal connected to the first back wiring pattern below the back inter-wiring insulating film.

15. The semiconductor device of claim 11,
wherein a height of the contact pattern in the vertical direction is smaller than a thickness of the semiconductor substrate in the vertical direction.

16. A semiconductor device including a first region and a second region, the semiconductor device comprising:
a semiconductor substrate including a first side and a second side that is on an opposite side of the semiconductor substrate from the first side;
a first active pattern on the first side of the first region;
a first gate structure that intersects the first active pattern;
a first source/drain region connected to the first active pattern, on a side face of the first gate structure;
a second active pattern on the first side of the second region;
a second gate structure that intersects the second active pattern;
a second source/drain region connected to the second active pattern, on a side face of the second gate structure;
an interlayer insulating film that covers the first gate structure, the first source/drain region, the second gate structure, and the second source/drain region, on the first side;
a front wiring structure on the interlayer insulating film;
a first back wiring pattern on the second side of the first region;
a second back wiring pattern on the second side of the second region, which second back wiring pattern is separated from the first back wiring pattern;
a back source/drain contact that penetrates the semiconductor substrate of the first region, and connects the first source/drain region and the first back wiring pattern; and
a contact pattern in the semiconductor substrate of the second region, wherein the contact pattern is connected to the second back wiring pattern,
wherein a first thickness of the semiconductor substrate of the first region is smaller than a second thickness of the semiconductor substrate of the second region, in a vertical direction intersecting the first side, and
a first height of the back source/drain contact in the vertical direction is larger than a second height of the contact pattern in the vertical direction.

17. The semiconductor device of claim 16,
wherein the second height is smaller than the second thickness.

18. The semiconductor device of claim 16,
wherein the contact pattern overlaps the second source/drain region in the vertical direction.

19. The semiconductor device of claim 16,
wherein the first source/drain region is configured to have a power supply voltage applied thereto through the first back wiring pattern and through the back source/drain contact.

20. The semiconductor device of claim 16, further comprising:
a third back wiring pattern separated from the second back wiring pattern; and
a through via that extends in the vertical direction, and connects the front wiring structure and the third back wiring pattern,
wherein the second source/drain region is configured to have a power supply voltage applied thereto through the third back wiring pattern, the through via, and the front wiring structure.
